(19) United States
(12) Patent Application Publication
(10) Pub. No.: US 2026/0116208 A1
(43) Pub. Date: Apr. 30, 2026

(54) DISCHARGE CONTROL CIRCUIT, CORRESPONDING SYSTEM, VEHICLE AND METHOD

(71) Applicant: STMicroelectronics International N.V., Geneva (CH)

(72) Inventor: Davide Cariaggi, Pesaro (IT)

(21) Appl. No.: 19/337,611

(22) Filed: Sep. 23, 2025

(30) Foreign Application Priority Data
Oct. 24, 2024 (IT) 102024000023709

(51) Int. Cl. B60L 15/08; B60L 15/22; H02M 1/32

(52) U.S. Cl. CPC B60L 15/08; B60L 15/22; H02M 1/322; B60L 2240/427

(57) ABSTRACT

A discharge control circuit comprises drive circuitry applying to a control terminal of an electronic switch a pulsed discharge signal, and producing pulses in the pulsed discharge signal with a duration that is a function of a voltage applied to the control terminal of the electronic switch sensed at a sensing node. The circuit also comprises a feedback network including a reference generator producing a signal indicative of a reference duration for the pulses in the pulsed discharge signal, and a pulse duration generator coupled to the sensing node to produce a duration signal indicative of the actual duration the pulses in the discharge signal. A pulse duration comparator coupled to the reference generator and the pulse duration generator acts on pulse duration control circuitry to control the duration of the pulses in the pulsed discharge signal applied to the control terminal of the electronic switch.

### CROSS-REFERENCE TO RELATED APPLICATIONS

This application claims priority to Italian Application No. 102024000023709, filed on Oct. 24, 2024, which application is hereby incorporated herein by reference.

### TECHNICAL FIELD

The description relates to discharge circuits.

One or more embodiments can be applied, for instance, in traction systems for electric vehicles (EVs) or power conversion systems exploiting a high-voltage energized element for filtering or stability purposes.

More generally, solutions as described herein can be applied to any type of apparatus where fast de-energization for functional and/or safety purposes is a desirable feature.

### BACKGROUND

Traction inverters for EVs may include a high-voltage (HV) capacitor, currently referred to as direct-current (DC) link capacitor, briefly, DC-Link.

Such a capacitor may be a rather “huge” component, having a high capacitance value (1 mF or even more) which may be charged to high voltages, in excess of 800 V, for instance.

In high-voltage (HV) systems like DC-DC converters and traction inverters, the HV DC-Link capacitors in the system should desirably be quickly discharged in scenarios such as (for instance) motor ignition OFF, loss of LV battery power supply, and communication with controller MCU lost/MCU not functional.

The DC-Link voltage should desirably be discharged below 60V in less than 1 s in order to prevent electrical shock hazard or the generation of unwanted torque.

DC-Link capacitors are commonly used in power converters as an intermediary buffer between an input source to an output load. An HV (up to >1 kV) plastic film capacitor with a capacitance of a few hundreds of μF or the parallel connection of several smaller capacitors can be used for that purpose.

Document EP 3 975 402 B1 and the corresponding U.S. Pat. No. 11,648,896 B2 can be referred to for an extensive discussion of the related issues.

Documents such as US 2019/058403 A1, US 2015/338866 A1, US 2008/284402 A1, US 2023/170790 A1, US 2010/320981 A1 or US 2022/285922 A1 provide additional insight into the related art.

Conventional solutions may benefit from being improved in respect of various points such as controlling the actual “on” time of external MOSFET/SiCFET/IGBT components (switches) may turn out to be difficult due to different characteristics of the switch technology and the driving strategy that is applied: in some cases, the actual “on” time may be too long, leading to excessive currents in the bridge, or too short, and thus unable to turn on an external switch; controlling the loop delay may in some cases cause excessive currents that may damage an external switch; a trial-and-error approach may be involved in finding correct settings of function parameters that may largely depend on system characteristics (battery voltage, switch gate charge, and so on).

### SUMMARY

An object of solutions as described herein is to contribute in addressing the various issues outlined in the foregoing.

According to one or more solutions as described herein, such an object can be achieved via a circuit having the features set forth in the claims that follow.

One or more solutions as described herein relate to a corresponding system. A traction system for an electric vehicle (EV) may be exemplary of such a system.

One or more solutions as described herein relate to a corresponding vehicle, such as an electric vehicle (EV).

One or more solutions as described herein relate to a corresponding method.

The claims are an integral part of the technical teaching provided herein in respect of the embodiments.

Solutions as described herein avoid excessive phase leg currents which may be caused by comparator latency in conventional solutions.

Solutions as described herein facilitate using power switches exhibiting different values for Qg (Qg=Total Gate Charge, that is the total amount of charge required to switch between on and off states) avoiding limitations of conventional solutions. Achieving an actual desired turn-on pulse duration is thus facilitated.

Conventional solutions may in fact have a limited number of fixed driver turn-on duration configurations. Having fixed driver turn-on times means that the charge transferred to the gate of an external switch is pre-determined: if very short turn-on times are set, switches with small Qg can be used but switches with large Qg cannot be used, and vice versa if longer times are used.

Solutions as described herein overcome this problem by making the mechanism independent of the Qg of external switches, by detecting (measuring) the actual time the gate voltage is above a turn-on threshold.

In solutions as described herein, a peak current value can be estimated via a (simple) calculation prior to system tests (which facilitates faster and easier implementation) as a function of the stray inductance between a DC-Link and ground.

Solutions as described herein use a controlled shoot-through technique (based on a comparison between the actual time the gate-source voltage is over a threshold with a selected shoot-through time) that facilitates using controlled shoot-through even in 800V systems and in the presence of (very) small parasitic inductances on the output loop, with the ability to discharge “huge” capacitors without damaging the drivers.

### BRIEF DESCRIPTION OF THE DRAWINGS

One or more embodiments will now be described, by way of example only, with reference to the annexed figures, wherein:

FIG. 1 is a functional block diagram of a traction system for an electric vehicle (EV) which is exemplary of a possible context of use of solutions as described herein;

FIG. 2 is circuit diagram exemplary of an approach that may be used in implementing a solution as illustrated in FIG. 1;

FIG. 3 is an exemplary block diagram of a solution as described herein;

FIG. 4 is a timing diagram exemplary of time behaviors (waveforms) of signals which may occur in solutions as described herein; and

FIG. 5 is an exemplary circuit diagram of a possible way of implementing various blocks illustrated in FIG. 3.

The figures are drawn to clearly illustrate relevant aspects of the solutions described herein and are not necessarily drawn to scale.

The edges of features drawn in the figures do not necessarily indicate the termination of the extent of the feature.

### DETAILED DESCRIPTION OF ILLUSTRATIVE EMBODIMENTS

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular configurations, structures, or characteristics may be combined in any adequate way in one or more embodiments.

The headings/references used herein are provided merely for convenience and hence do not define the extent of protection or the scope of the embodiments.

Unless the context indicates otherwise, like parts or elements are indicated throughout the figures annexed herein with like references/numerals and a corresponding description will not be repeated for the sake of brevity.

For the sake of simplicity and ease of explanation, a same designation may be applied throughout this description to designate: a node or line as well as a signal occurring at that node or line; a component (such as a capacitor, resistor or inductor of coil) as well as electrical parameters thereof.

Also, when it is mentioned that an element is “connected to” or “coupled to” another element, it should be understood that still another element may be interposed therebetween as well as that the element may be connected or coupled directly to another element.

On the contrary, when it is possibly mentioned that an element is “connected directly to” or “coupled directly to” another element, it should be understood that still another element is not interposed therebetween.

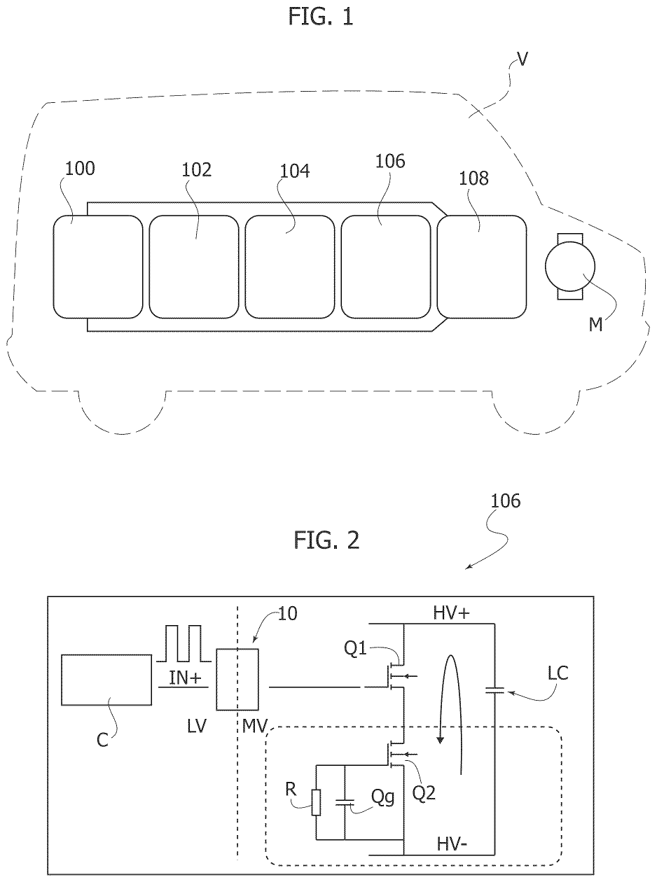

FIG. 1 is a functional block diagram of a traction system for an electric vehicle (EV) designated V, whose outline is schematically reproduced in dashed lines.

It is once more recalled that, while traction systems in electric vehicles (EVs) will be primarily discussed in this exemplary description, the solutions described herein are not limited to that possible context of use.

One or more solutions described herein can be applied, for instance, in power conversion systems exploiting a high-voltage energized element for filtering or stability purposes or, more generally, in contexts involving fast de-energization for functional and/or safety purposes.

Advantageous applications of solutions as described herein include various sub-systems in Hybrid Electric Vehicle (HEV)/Battery Electric Vehicle (BEV) such as high-voltage DC links (200V to 800V) and high-voltage galvanic isolated drivers up to 1 kV as used in motor control inverters (switched-mode power supplies, SMPS).

Irrespective of the intended application, reducing system size, cost and components count are desirable targets to pursue in implementing a (DC-Link, for instance) discharge avoiding dedicated additional circuitry, possibly using an existing stage (three-phase inverter, for instance) for this purpose.

Such a discharge function can be implemented by placing high-power resistors in parallel to a DC-Link: a switch in series to the resistors is closed whenever the DC-Link is desired to be discharged, so that discharging the capacitor over the resistors facilitates limiting the discharge current and to dissipate the resulting power.

A solution to discharge a DC-Link without an additional circuitry involves simultaneously turning on (making conductive) high-side and low-side switches on one or more phase leg to cause a shoot-through event: this condition should otherwise be controlled in order to counter system damage due to over-currents; if left uncontrolled, the current during shoot-through can reach a value of several kA in a few ns, with a steep dI/dt of tens of A/ns.

A system as presented—by way of example—in FIG. 1 includes a (multi-phase) electric motor M driven by a drive chain based on electronic circuitry comprising integrated circuits (semiconductor chips or dice).

Such a drive chain as illustrated in FIG. 1 may comprise, for instance: a set of low-voltage (LV) die safety mechanisms 100, a first high-voltage (HV) die group 102 configured to provide functions such as undervoltage (UV)/overvoltage monitoring for voltage-high (OV VH), undervoltage monitoring for voltage-low (UV VL), thermal shutdown, watchdog; brake control 104; a second high-voltage (HV) die group 106 configured to provide functions such as desaturation (DES), current sensing (overcurrent/short circuit—ISEN), overtemperature (TSEN OT) as well as shoot-through discharge as discussed in the following; a third high-voltage (HV) die group 108 configured to provide functions such as active VDS/VCE clamping (VCECLAMP), overvoltage monitoring for voltage-low (OV VL), gate command voltage monitor (VGE).

This is a safety mechanism checking consistency of a received gate drive logic command with the status of HV driver gate. For instance, if the HV driver receives an OFF command from the control logic, the gate voltage of the HV driver should fall below an “OFF” threshold within a defined (possibly programmable) filter time.

It will be otherwise appreciated that, with the exception of the shoot-through discharge function as discussed in detail in the following (which can be advantageously included in the second high-voltage die group 106) the arrangement illustrated in FIG. 1 can be regarded as per se conventional in the art: a more detailed description will not be provided herein for brevity.

A traction inverter for an electric vehicle (EV) driving an electric motor M (including three sets or “phases” of windings energized via respective electronic switches such as power transistors according to a Space Vector Modulation scheme) may be exemplary of such a conventional arrangement.

For simplicity of presentation and explanation, this description will refer primarily to a single phase (and a single switch), being otherwise understood that the same principles discussed herein can be extended to plural phases/switches.

Also, the vehicle V illustrated in FIG. 1 is merely exemplary of one of a variety of possible contexts of use of solutions as described herein: as noted, solutions as described herein can be implemented in systems (DC/DC or AC/DC or DC/AC converters, just to mention a few examples) where an energized element is desired to be discharged within a short time.

Document EP 3 975 402 B1 and U.S. Pat. No. 11,648,896 B2 (both already cited) describe a discharge control circuit as well as a corresponding system, a corresponding vehicle and a corresponding method suited of use in such a context along the lines of FIG. 2.

In FIG. 2 an energized element is shown including a high-voltage (HV) capacitor LC, currently referred to as direct-current (DC) link capacitor, or, briefly, DC-Link.

Such a capacitor may be a rather “huge” component, having a high capacitance value (1 mF or even more) which may be charged to high voltages, in excess of 800 V, for instance.

Like the solutions described in the earlier documents already repeatedly cited, the solutions described herein again address the problem of providing a shoot-through discharge function which can be advantageously implemented in connection with an isolated-gate driver 10 providing galvanic isolation between a low-voltage side LV and a high voltage side HV, this latter including two power switches Q1 and Q2 arranged between high voltage rails HV+ and HV− with a capacitor LC coupled therebetween.

The two power switches Q1, Q2 may include power transistors such as (Silicon Carbide or SIC) power MOSFETs or Insulated Gate Bipolar Transistors (IGBTs).

In the exemplary case illustrated in FIG. 2, the two power switches designated Q1 and Q2 are exemplary of “phase” switches of the motor M of FIG. 1, with the parallel connection of a resistor R and a capacitor Qg coupled to the gate of Q2.

It is noted that in an arrangement as exemplified herein the transistors Q1 and Q2 do not represent additional switches used to implement the shoot-through discharge function: in an arrangement as exemplified herein, the transistors Q1 and Q2 are “functional” switches used to drive an electrical load LC.

For instance, the transistors Q1 and Q2 may be the switches that drive the “U” phase of a motor M as illustrated in FIG. 1, with other pairs of switches (currently referred to as Q3/Q4 and Q5/Q6, not visible for simplicity) used to drive the “V” phase and the “W” phase, respectively, of the motor M.

By way of summary of the disclosure in EP 3 975 402 B1/U.S. Pat. No. 11,648,896 B2: these switch (transistor) pairs may also provide an ASC (Asynchronous Stop Command) feature (a safety feature that brakes the motor M in the presence of conditions militating against effective control of the motor torque); a shoot-through function can be implemented in parallel on the three phases, which may thus co-operate in discharging the DC-Link during shoot-through and/or can be advantageously implemented in the HV domain, via a redundant logic such as a safety MCU, for instance; advantageously, the shoot-through function can be implemented (wholly) on the HV side exploiting the same signal path as the ASC function, without penalizing temporal resolution; a shoot-through command IN+ can be generated as a functional signal (produced as a backup by a controller C such as a MCU included in a system as illustrated in FIG. 1), with lower priority than any other safety mechanism; for instance, a backup MCU in the low-voltage (LV) domain may generate (in a manner known per se to those of skill in the art) a IN+ signal as a PWM signal to be transformed into shoot-through pulses; solutions described herein may exploit a brake pin (currently used to implement the ASC function discussed previously) in order to trigger the shoot-through action. This may involve implementing “fuzzy” logic circuitry with a double-threshold comparator capable of distinguishing an ASC request from a shoot-through request; a single pin can be advantageously used to implement two functions with no penalties in terms of pin count with a shoot-through command also considered as a safety path signal, with—for instance—a backup MCU in the high-voltage (HV) domain applying a signal such as a PWM brake signal (see block 104 in FIG. 1) to be transformed into shoot-through pulses.

Again, a factor of interest in implementing a DC-Link discharge function as discussed herein lies in limiting the discharge current by controlling the switch-on time of a discharge switch, which can be managed directly, while avoiding the inherent drawbacks of those techniques where the current can be limited through the RDSon (drain-to-source resistance of the switch when conductive) of the low-side switch.

To that effect, in solutions described herein may be applied to an approach where a high-side switch is forced to a steady “on” (conductive) state and a PWM (Pulse-Width-Modulated) signal is applied to a low-side switch, having a TON value (switch conductive) which is higher than a desired “on” time.

Solutions as described herein may be applied to a complementary approach where the low-side switch is forced to a steady “on” state and a PWM signal is applied to the high-side switch. Both strategies can be considered viable to perform effective shoot-through discharge.

System software can select either strategy depending on the initial scenario before starting the procedure (e.g., state of the HS/LS switches, presence of short failures, and other factors influencing the choice of the discharge strategy). The related ON/OFF signals can be managed via a “safing” logic C on the LV side (see FIG. 2, by way of example) and on the HV side, with an ASC capability via a BRAKE signal maintained as discussed previously.

It is noted that a safing logic in the LV domain will disable a related interlock prior to implementing the shoot-through action. Conversely, with a safing logic in the HV domain, interlocking is implemented in the LV die and is thus bypassed.

As discussed, by referring to an exemplary—yet not mandatory—application to traction inverters, solutions as described herein are intended to improve system behavior in the presence of various issues which may arise in response to certain conditions (motor “ignition” discontinued or off, IGN OFF, for instance), where it is desired to discharge the DC-Link (essentially, the capacitor LC) to counter an undesirably high storing of energy in the high-voltage or HV domain (when the vehicle V is not powered, for instance).

As repeatedly noted, such a capacitor may be a rather “huge” component, having a high capacitance value (1 mF or more) which may be charged to high voltages, in excess of 800 V, for instance.

In arrangements as exemplified in FIG. 1 a passive discharge function can be (already) provided for general safety purposes, implemented by means of bleeding resistors, for instance. This facilitates a constant, yet fairly slow discharge path.

An active discharge function may also be provided subject to “enable” acts, for instance in case of a collision (car crash) or when a high-voltage protective cover of an electronic control unit (ECU) is removed for maintenance purposes. For instance, such an active discharge function can be implemented by means of a dedicated switch whose energy is limited by series resistors. Such a function can bring the DC-Link voltage below 60V in less than 1 s, to prevent electric shock risk.

Such an active discharge function can be implemented on a HV NMOS-based board (mounted as low-side) and configured to be normally inactive (OFF), since the interlock short-circuits the gate-source voltage (VGS).

In response to a HV safety box cover being opened, the interlock is released, with a VGS self-generated from the DC-Link voltage and clamped by a discharge diode with the NMOS transistor maintained conductive (ON) until the DC-Link is fully discharged.

One or more solutions as described herein may exploit the traction module “phase” switches for the purpose of (rapidly) discharging the DC-Link while avoiding the risk of (serious) damage due to uncontrolled discharge current. Such an approach is beneficial in terms of cost reduction, and takes advantage of a precise shoot-through timing control in order not to overstress the phase switches by repeated overcurrent events.

In a context as exemplified in FIG. 1, the three-phase switches in the “legs” of the motor M can thus be used in the place of a LS NMOS transistor as in the case of active discharge as discussed previously.

In one or more solutions as described herein (phase) interlocking is temporarily disabled, with the high-side HS (the low-side LS, respectively) kept permanently conductive (ON) and the low-side LS (the high-side HS, respectively) switched alternatively ON/OFF in a PWM mode to generate a shoot-through as desired.

As discussed previously, in solutions as exemplified herein, the current is not limited via resistors and can be controlled by accurately modulating the shoot-through time interval.

This facilitates taking into account the fact that the discharge current may rise with a 10 A/ns slope, which amounts to reaching values as high as 4 kA in 400 ns, which may result is serious damage.

Also, solutions as exemplified herein facilitate providing a closed-loop control of the conduction times of a discharge switch. This makes it possible to avoid contingencies where an “ON” command sent towards that switch may be subject to a propagation delay estimated inaccurately to the point that the switch may be undesirably forced to an “OFF” state immediately after receiving the “ON” command, or even prevented from receiving the “ON” command, thus remaining in an “OFF” state.

Referring to application scenarios as generally illustrated in FIGS. 1 and 2, the interlocking function can be temporarily disabled on both HS and LS drivers.

Advantageously, solutions as described herein can be applied in connection with an isolated-gate driver of the type currently available under the trade designations L9502 with companies of the STMicroelectronics group (see st.com)

In an isolated-gate driver of the L9502 family: a high-side (HS) field-effect transistor (FET) can be turned on (made conductive) permanently while DES/ISEN (DESATURATION e OVERCURRENT/SHORT CIRCUIT) protections will be active and configured as desired; and a low-side (LS) field-effect transistor (FET) can be driven with a pulse-width-modulated PWM signal (e.g., 20 kHz) at a low duty-cycle, which corresponds to a reduced value for the “on” time TON in comparison with the “off” time TOFF.

Advantageously, the value for TON generated by the associated controller (MCU) is selected higher than the propagation delay of the whole chain.

For instance, having a value for TON of (at least) 10 μs facilitates correct operation, avoiding undesired “skipped” pulses. This may result in duty-cycles up to 50%, with pulse duration modulated as discussed in the following.

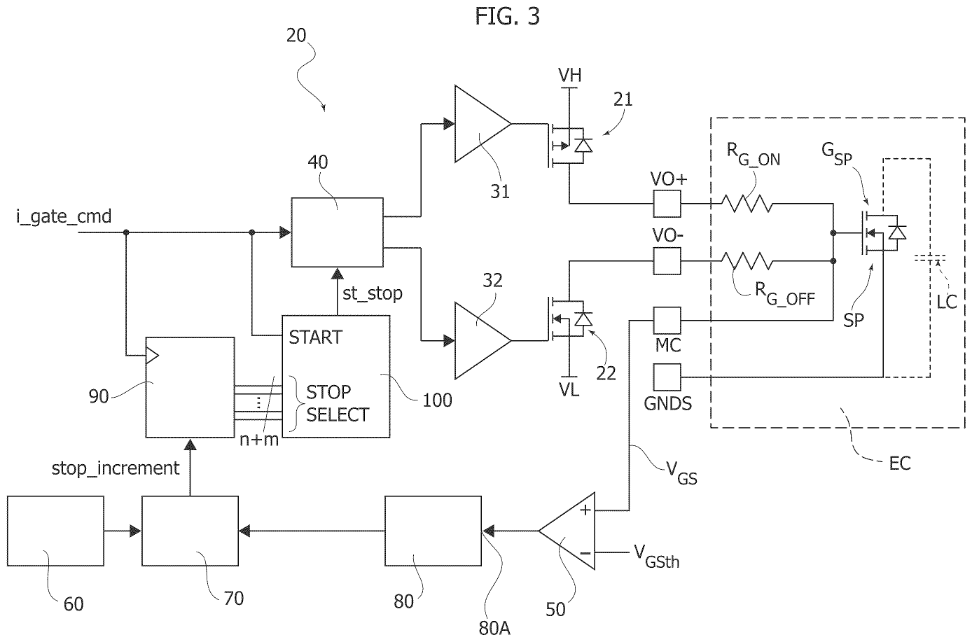

FIG. 3 is a circuit diagram of an exemplary discharge circuit 20 which can be advantageously included in an arrangement as illustrated in FIGS. 1 and 2.

Again, it is noted that reference to such an arrangement shall not be construed in a limiting sense: one or more embodiments can be implemented in systems (DC/DC or AC/DC or DC/AC converters, just to mention a few examples) where an energized element is desired to be discharged within a short time, that is systems where fast de-energization for functional and/or safety purposes is a desirable feature.

For that reason, FIG. 3 generally refers to a discharge circuit (20 as a whole) configured to discharge an energized element (a DC-Link capacitor LC, shown in dashed lines, for instance) via at least one electronic switch SP.

By way of example, in an operating context as illustrated (in an exemplary and non-limiting manner) in FIG. 1, the electronic switch SP may be one of the “phase” switches of the motor M of an electric vehicle V configured to be operated according to a Space Vector Modulation scheme as conventional in the art.

Such an electronic switch SP includes a control terminal GSP (a gate, in the case of a field-effect transistor—either Si or SiC-based—or an IGBT).

Briefly, a discharge control circuit 20 as illustrated in FIG. 3 comprises a pair of electronic switches 21, 22 (power MOSFET transistors, for instance, p-type for MOSFET 21 and n-type for MOSFET 22).

Such a circuit 20 can be integrated as a pre-driver stage (for instance, in a device of the L9502 family as discussed previously) and coupled to a discharge circuit including switches Q1 e Q2 as illustrated in FIG. 2.

For instance, a circuit 20 as exemplified in FIG. 3 can be configured to (pre)drive a respective switch Qx in a traction inverter so that six circuits 20 can be provided in a traction inverter for driving the U, V and W phases in an electric motor, each phase including two switches such as Q1 and Q2.

For the sake of simplicity and ease of explanation, the structure and operation of a single circuit 20 coupled to a single (discharge) switch SP will be discussed in the following.

A circuit 20 as illustrated in FIG. 3 comprises: a first (high-side or HS) switch 21 coupled between a first (high-side) voltage node VH and a first output node VO+, and a second (low-side or LS) switch 22 coupled between a second output node VO− and a second (low-side) voltage node VL.

The switches 21, 22 have their control terminals (gates, in the case of field-effect transistors such as MOSFETS) coupled to the outputs of respective drive circuits 31, 32.

As illustrated in FIG. 3: the switch 21 is arranged with the current flow path therethrough (source-drain in the case of a field-effect transistors such as a MOSFET) between the high-side voltage node at a voltage VH and a first output node VO+, and
the switch 22 is arranged with the current flow path therethrough (source-drain in the case of a field-effect transistor such as a MOSFET) between a second output node VO− and the low-side voltage node at a voltage VL.

The drive circuits 31, 32 are in turn controlled by a gate drive logic circuit 40 to which a pulsed command signal i_gate_cmd (generated in a manner known per se to those of skill in the art) is applied.

The switch drives/types are configured in such a way that the switches 21, 22 can be switched on and off (made conductive and non-conductive) to vary the voltages at the nodes VO+, VO− that are applied (via resistors RG_ON and RG_OFF) to the control terminal GSP (gate, in the case of field-effect transistor such as a power MOSFET) of the electronic switch SP.

That is, a pre-driver output stage as exemplified herein comprises a stage including the switches 21 and 22 forming a “split” output (VO+/VO−). Turning on (making conductive) the switch GSP can be achieved via the VO+ output, and the transition speed can be trimmed by changing the resistance value of the resistor RG_ON. Similarly, turn-off at the gate GSP can be achieved via the VO− output, and the transition speed can be trimmed by changing the resistance value of the resistor RG_OFF.

Also, while exemplified herein as a MOSFET, the switch SP may comprise any type of voltage-controlled power element such as a regular MOSFET, a Silicon Carbide (SiC) MOSFET, an Insulated Gate Bipolar Transistor (IGBT) or a Gallium Nitride (GaN) transistor, for instance.

As noted, the switch SP can be included in one of the “phases” (referred to ground GNDS, for instance) of an electric motor such as M in FIG. 1.

The representation of FIG. 3 highlights the fact that the (power) switch SP—having a current flow path therethrough (source-drain in the case of a field effect transistor such as a MOSFET transistor) referred to ground GNDS—as well as the element energized thereby and the resistors RG_ON and RG_OFF may be “external” components (EC) distinct from the circuit 20.

As such, these components may be intended to be coupled to the circuit (at nodes VO+, VO−, MC, GNDS) only by an end user (when producing the vehicle V of FIG. 1, for instance): in fact, both the switch SP and the energized element (a rather “huge” component in the case of a DC-Link capacitor) may have a considerable size.

Reference 50 in FIG. 3 denotes a comparator configured to compare the voltage at the control terminal (gate) of the electronic switch SP (as sensed at the node MC) with a (configurable) turn-on threshold value VGSth, produced in a manner known per se to those of skill in the art.

Contemplating the presence of the comparator 50 may be advantageous in so far as such a comparator may be already included for safety/diagnostic purposes as 2LTO comparator in an isolated-gate driver of the L9502 family as repeatedly discussed in the foregoing.

In an arrangement as discussed so far, adequately controlling the actual “on” time (conduction time) of the external switch SP may turn to be critical if different technologies, and thus different characteristics of the switch SP, come into play.

In fact, in certain cases, the actual “on” time may be too long and cause an undesirably high current to flow in the bridge; in other cases, the actual “on” time may be too short and thus unable to switch the external switch SP.

A current that is too high (as possibly caused by a delay in the control loop) may damage the external switch.

In principle, a trial-and-error approach might be resorted to in order to find a correct setting of operation parameters that depend on system characteristics such as battery voltage, switch gate charge Qg, and so on.

Solutions as described herein address these issues by comparing a pulse duration TSHOOT taken as a reference (as set, in a manner known per se to those of skill in the art) with the actual value of the “on” time applied to the control terminal (gate GSP) of the external switch SP.

For instance, the pulse duration TSHOOT can be set in a reference pulse generator 60 (as a configurable n-bit word, for instance) and a resulting signal from the generator 60 applied to a comparator 70 to be compared therein with a signal produced in another pulse generator 80 that is coupled to the node MC.

This advantageously occurs via the comparator 50 whose output drives a start/stop input 80A of the generator 80.

The comparator 50 compares against a (configurable) threshold VGSth a signal VGS applied (via the resistors RG_ON and RG_OFF) to the control terminal (gate GSP) of the external switch SP as sensed at the node MC.

The signal from the generator 80 is thus indicative of the (actual) duration of the pulses (“on” time) applied to the control terminal (gate GSP) of the external switch SP.

As exemplified in FIG. 3, a DAC-based (n+m bit) counter 90 receives the signal i_gate_cmd applied to the gate driver logic circuitry 40 as well as a signal stop_increment from the comparator 70.

The counter 90 can be configured to count each pulse in the signal i_gate_cmd until the signal stop_increment from the comparator 70 becomes equal to “1”. The signal stop_increment becomes “1” in response to the signals from the generators 60 and 80 being found to correspond by the comparator 70.

Essentially, the counter 90 is configured to select when a stop command st_stop should be provided to the gate driver logic circuitry 40 via a pulse generator 100.

This can be a configurable, n+m bit generator.

For instance, the duration of the output pulse may start from 1 LSB of the pulse generator 100 and be incremented by 1 LSB steps at each cycle of the i_gate_cmd pulse by the DAC-based counter 90.

To summarize, FIG. 3 illustrates by way of example a circuit 20 that comprises drive circuitry (for instance the elements 21, 22, 31, 32, 40) configured to be coupled (via the nodes VO+, VO− and the resistors RG_ON, RG_OFF) to a control terminal GSP (the gate, in the case of a field-effect transistor) of an electronic switch SP (such as a field-effect transistor, in the example illustrated).

The drive circuitry 21, 22, 31, 32, 40 is configured to apply to the control terminal GSP a pulsed discharge signal (via the nodes VO+, VO−) that comprises pulses causing the electronic switch SP to become conductive and provide an electrical discharge path for an energized element LC, within the framework of a (controlled) shoot-through action.

The exemplary circuit 20 illustrated in FIG. 3 comprises a sensing node MC intended to be coupled to the control terminal GSP in order to sense the voltage at that control terminal as well as a feedback network (for instance the elements 50, 60, 70, 80, 90, 100) from the sensing node MC to the drive circuitry 21, 22, 31, 32, 40.

Thanks to this feedback action from the sensing node MC the drive circuitry can produce the pulses in the pulsed discharge signal (at the nodes VO+, VO−) with a duration that is a function of the voltage VGS at the control terminal GSP as sensed at the sensing node MC.

In the exemplary circuit 20 illustrated in FIG. 3, the feedback network comprises: a reference generator 60 configured to produce a reference signal indicative of a reference duration (referred to as TSHOOT) for the pulses in the pulsed discharge signal, a pulse duration generator 80 that is coupled (via the comparator 50, for instance) to the sensing node MC and configured to produce a (pulsed) duration signal indicative of the actual duration the pulses in the pulsed discharge signal, a pulse duration comparator 70 that is coupled to the reference generator 60 and the pulse duration generator 80.

In the exemplary circuit 20 illustrated in FIG. 3: the pulse duration comparator 70 is configured to compare the actual duration of the pulses in the pulsed discharge signal with the reference duration TSHOOT for the pulses in the pulsed discharge signal; and pulse duration control circuitry (the elements 90 and 100) is provided coupled to the drive circuitry 21, 22, 31, 32, 40 to control the duration of the pulses in the pulsed discharge signal applied by the drive circuitry 21, 22, 31, 32, 40 to the control terminal GSP of the electronic switch SP.

The pulse duration control circuitry 90, 100 exemplified herein is coupled to the pulse duration comparator 70 and is configured to: increase the duration of the pulses in the pulsed discharge signal if the pulse duration comparator 70 indicates that the actual duration the pulses in the pulsed discharge signal is shorter than the reference duration TSHOOT; and refrain from increasing (that is, stop increasing) the duration of the pulses in the pulsed discharge signal if the pulse duration comparator 70 indicates that the actual duration of the pulses in the pulsed discharge signal has reached or exceeded the reference duration TSHOOT.

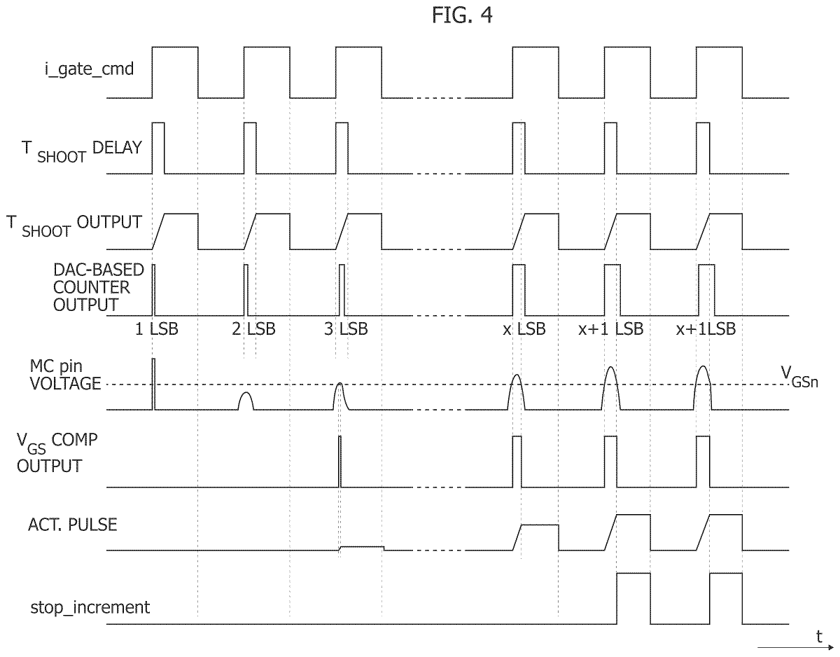

FIG. 4 is a timing diagram exemplary of time behaviors (waveforms) of signals which may occur in a possible implementation of solutions as described herein.

More specifically, the diagram of FIG. 4 reports—against a common abscissa time scale t—possible time behaviors (waveforms) of various signals that can be regarded essentially as isochronous with the signal i_gate_cmd (uppermost curve in FIG. 4) applied to the gate driver logic circuitry 40, the DAC-based counter 90 and the pulse generator 100.

Proceeding from top to bottom of FIG. 4 below the curve for i_gate_cmd, possible time behaviors are illustrated of the following signals: TSHOOT DELAY, that represents a target “on” time duration TSHOOT for the control terminal (gate) for the external switch SP (a FET transistor, in the case illustrated herein); as discussed, the value TSHOOT can be set in the reference generator 60 as a configurable n-bit word; TSHOOT OUTPUT, namely the output from the reference generator 60, here represented as a pulsed signal wherein the pulses start with a rising slope having a duration set by the pulses of the signal TSHOOT DELAY; as a result, the amplitude of the pulses in the signal TSHOOT OUTPUT is indicative of the target “on” time duration for the control terminal (gate) for the external switch SP; DAC-BASED COUNTER OUTPUT, namely the output from the counter 90; MC pin VOLTAGE, namely the voltage at the node MC, which is indicative of the signal VGS applied to the control terminal (gate GSP) of the external switch SP; VGS COMP OUTPUT, namely the output from the comparator 50: the duration of the pulses in the signal VGS COMP OUTPUT is indicative of the actual current “on” time applied to the control terminal (gate) for the external switch SP; ACT.PULSE, namely the output from the pulse generator 80: this is zero as long as the signal VGS is lower than the (configurable) threshold VGSth and gradually increases in response to the signal VGS reaching and exceeding the threshold; as exemplified herein, the pulses in the signal ACT.PULSE start with a rising slope having a duration set by the duration of the pulses of the signal VGS COMP OUTPUT from the comparator 50: as a result, the amplitude of the pulses in the signal ACT.PULSE is indicative of the actual current “on” time applied to the control terminal (gate) for the external switch SP; and stop_increment, namely the signal from the comparator 70, which becomes equal to “1” in response to the signals TSHOOT OUTPUT and ACT.PULSE from the generators 60 and 80 being found to correspond in the comparator 70; this occurs in response to the actual current “on” time duration applied to the control terminal (gate) GSP for the external switch SP having reached (and possibly exceeded) the target “on” time duration TSHOOT set in the reference generator 60, so that further increments of the output from the counter 90 can be stopped (at a value x+1 LSB, for instance: see the rightmost portion of the curve for DAC-BASED COUNTER OUTPUT in FIG. 4).

To summarize, FIG. 4 exemplifies operation of an exemplary (and otherwise non-mandatory) implementation of solutions as described herein where: the comparator 50 (with a programmable threshold VGSth) controls the start/stop (on/off) state of the pulse generator 80; in the comparator 70, the output from the generator 80 is compared with the (reference) output from the generator 60; the result of the comparison in the comparator 70 is used to stop increments of the DAC-based counter 90 in response to the output from the generator 80 (indicative of the actual pulse duration) reaching and possibly exceeding the output from the reference generator 60 (indicative of the programmed value for TSHOOT).

When increments are stopped in the DAC-based counter 90, the counter 90 refrains from further incrementing its count value, and the final count value reached is maintained during the discharge process.

In that way, the actual “on” time can be controlled, thus countering an undesired high current flow through the bridge (switches 21 and 22), which may damage the external switch SP.

If, based on the output from the generator 80, the comparator 70 determines that the actual pulse duration applied to the switch SP via the control terminal GSP falls below the value TSHOOT (as expressed by the output from the reference generator 60), the pulse duration from the DAC-based counter 90 is again increased: this counters any undesired situation where the actual “on” time may be too short and thus unable to switch the external switch SP.

That is, in a possible implementation as discussed herein, the reference generator 60 produces a signal TSHOOT DELAY which is indicative of the reference value TSHOOT and is compared with the signal generated by the generator 80, which in turn is indicative of the duration of the “on” pulses applied to the switch GSP: if this latter duration is shorter than TSHOOT (that is, TSHOOT is longer) the counter 90 keeps counting; if this latter duration is equal or longer than TSHOOT (that is, TSHOOT is reached or shorter) the counter 90 stops counting.

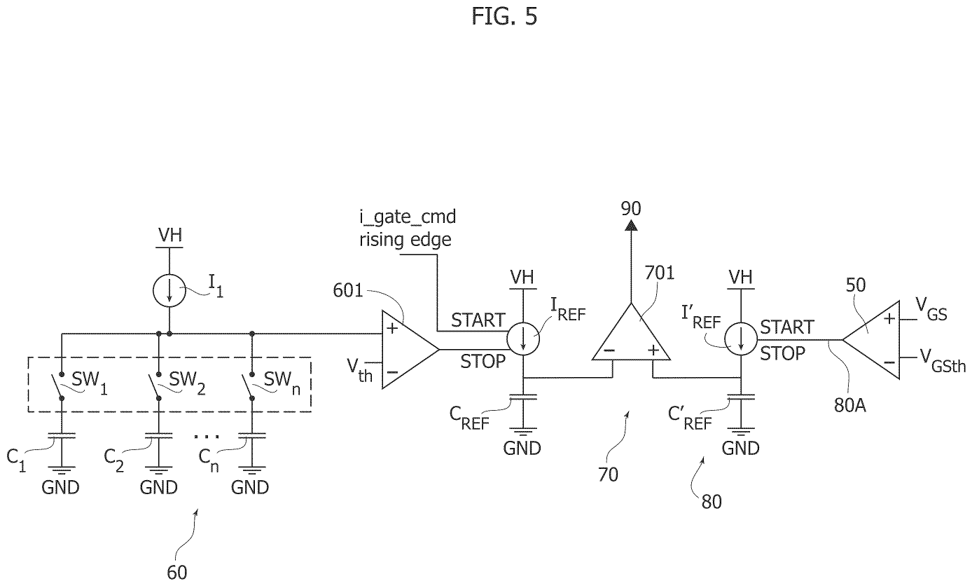

FIG. 5 is an exemplary circuit diagram of a possible way of implementing certain blocks that are illustrated in FIG. 3 (essentially: the reference generator 60, the pulse duration comparator 70 that asserts the stop-increment signal towards the counter 90, and the generator of the value for the “actual” pulse duration with a START/STOP input 80A coupled to the output from the comparator 50) and can operate as exemplified in the diagram of FIG. 4.

As illustrated (merely by way of example) the reference generator 60 may include a current generator I1 (of any known type) coupled to the “high” supply voltage VH and configured to charge capacitors C1, C2, . . . Cn in a bank of capacitors referred to ground GND via respective charge switches SW1, SW2, . . . , SWn that can be selectively closed (made conductive) according to an n-bit configuration word from a SPI interface (not visible for simplicity) corresponding to a desired value for TSHOOT.

The charge voltage of the capacitors C1, C2, . . . Cn is applied via common rail to an input (non-inverting, for instance) of a comparator 601 to be compared with a threshold value Vth.

The output from the comparator 601 is supplied (in response to the charge voltage of the capacitors C1, C2, . . . Cn exceeding the threshold Vth) as a STOP signal to a further current generator IREF (of any known type) coupled to the “high” supply voltage VH and configured to receive as a START signal a signal (generated in a manner know per se) linked to the rising edges of the signal i_gate_cmd.

The further current generator (reference generator) IREF is configured to charge (when activated via the START signal) a capacitor CREF referred to ground GND.

The voltage charged on the capacitor CREF is applied to a first input (inverting, for instance) of a comparator 701 that can be regarded as the core of the pulse duration comparator 70 of FIG. 3.

A still further current generator I′REF (of any known type) is coupled to the “high” supply voltage VH and configured to receive as START/STOP signal the applied at the input 80A by the comparator 50.

The further current generator I′REF (assumed for simplicity to produce a current equal to the current from the generator IREF) is configured to charge (when activated via the START signal) a capacitor C′REF (assumed for simplicity to have a capacitance equal to the capacitance of the capacitor CREF) referred to ground GND.

The voltage charged on the capacitor C′REF is applied to a second input (non-inverting, for instance) of the comparator 701 whose output is applied to the DAC-based counter 90 as discussed previously in connection with FIG. 3.

As noted, the one referred to in FIGS. 4 and 5 is an exemplary (and otherwise non-mandatory) implementation of solutions described herein.

Essentially, the comparison performed in the comparator 70 is a comparison of the duration of the time the signal VGS applied to the external switch SP with the duration of the reference value TSHOOT.

The implementation exemplified in FIG. 5 does this by loading two capacitors CREF, C′REF of equal capacity with equal currents IREF, I′REF and then comparing the resulting voltages: given the basic relationship between charge Q, voltage V and capacitance C in a capacitor (namely dQ/dt=i(t)=C*dV/dt) and considering a constant current i(t)=i, then i=C*ΔV/Δt. If the initial voltage on a capacitor is assumed to be 0V, the final voltage is proportional to the time Δt over which the current was applied: V=i*Δt/C.

It is noted that using two capacitors C_{REF}, C′_{REF} of equal capacity to be loaded with currents I_{REF}, I′_{REF} of equal intensity is not mandatory, provided the equality of the current-to-capacitance ratios I_{REF}/C_{REF} and I′_{REF}/C′_{REF} is maintained (namely I_{REF}/C_{REF}=I′_{REF}/C′_{REF}), that is, provided the ratio I_{REF}/C_{REF} of the intensity of the current I_{REF} from the first reference current generator and the capacitance C_{REF} of the first reference capacitor is equal to the ratio I′_{REF}/C′_{REF} of the intensity of the current I′_{REF} from the second reference current generator and the capacitance C′_{REF} of the second reference capacitor.

In the implementation referred to in FIG. 4 and FIG. 5, the (time) comparison of the duration of the “on” pulses applied to the switch SP with the reference value TSHOOT is based on a voltage reading (comparison), which facilitates an analog implementation.

As an alternative, a digital implementation of the same underlying concept may rely on a clock signal (a high frequency clock may be advantageous to obtain a good resolution), with the value TSHOOT defined as a number of clock “strokes” with the number of strokes corresponding to the “on” times of the signal applied to the switch SP measured (for instance by counting how many strokes this is above the threshold).

An analog implementation as described herein by way of example is advantageous, for instance in those applications operating with clock periods of 20-50 ns, that is with clock signals that may turn out to be too slow to achieve a resolution as desired using a digital implementation.

Whatever the specific implementation details, in solutions as described herein a programmed pulse duration TSHOOT is compared with the actual “on” time (VGS>VGSth in the comparator 50, for instance) on an external switch and the pulse duration in pulse width modulation PWM is increased until the programmed value is reached (or until actual on time is matched).

Advantageously: the output pulse duration starts at a small value (1 LSB, for instance) and is gradually increased (by that small value, for instance to 2 LSB, 3 LSB, . . . —see the curve for the signal DAC-BASED COUNTER OUTPUT in FIG. 4) each time the command to drive the gate is processed; a comparator such as the comparator 50 with a programmable threshold VGSth is used to control (at the input 80A) the on/off (start/stop) state of the pulse generator 80 and the output of the generator 80 is compared with the output of reference generator 60 to generate a comparison result (comparator 70); the comparison result thus stops the increments of the DAC-based counter 90 in response to the output from the pulse generator 80 indicating that the programmed value for TSHOOT has been reached (and possibly exceeded) and the final value from the DAC-based counter 90 (for instance at x+1 LSB—see the curve for the signal DAC-BASED COUNTER OUTPUT in FIG. 4) is maintained in the discharge process; the comparison results re-start the increments of the pulse duration set by the DAC-based counter 90 so that counter 90 is incremented when the programmed value for TSHOOT as given by the block 60 is higher than the duration of the pulses as derived from the block 80; and/or the counter 90 is reset when the circuit is reset (power supply cycle).

Adaptive controlled shoot-through as proposed herein counters undesired excessive phase leg currents due to latency in a comparator such as the comparator 50 and facilitates using power switches SP having of different Qg values with a desired turn on pulse duration.

Adaptive controlled shoot-through as proposed herein makes it possible to estimate the peak current prior to any actual system test, which facilitates faster and easier implementation.

For instance, a simple calculation facilitates estimating the peak current Ipeak based on the time derivative of the current in so far as: derivative of the current in so far as: di/dt=V_{DCLINK/}L_{stray}=>Ipeak≈(V_{DCLINK}/L_{stray})*T_{SHOOT} where Lstray is the stray inductance between the DC-Link and ground (GND).

Without prejudice to the underlying principles, the details and embodiments may vary, even significantly, with respect to what has been described by way of example only without departing from the extent of protection.

The extent of protection is determined by the annexed claims.

What is claimed is:

1. A circuit, comprising:
drive circuitry configured to be coupled to a control terminal of an electronic switch and to apply to the control terminal a pulsed discharge signal comprising pulses causing the electronic switch to become conductive and provide an electrical discharge path for an energized element;
a sensing node configured to be coupled to the control terminal and to sense a voltage at the control terminal; and
a feedback network from the sensing node to the drive circuitry, wherein the drive circuitry is configured to produce the pulses in the pulsed discharge signal with a duration that is a function of the voltage at the control terminal sensed at the sensing node, and wherein the feedback network comprises:
a reference generator configured to produce a reference signal indicative of a reference duration for the pulses in the pulsed discharge signal;
a pulse duration generator coupled to the sensing node and configured to produce a duration signal indicative of an actual duration of the pulses in the pulsed discharge signal;
a pulse duration comparator coupled to the reference generator and the pulse duration generator, the pulse duration comparator configured to compare the actual duration the pulses in the pulsed discharge signal with the reference duration for the pulses in the pulsed discharge signal; and
pulse duration control circuitry coupled to the drive circuitry and the pulse duration comparator, wherein the pulse duration control circuitry is configured to:
control the duration of the pulses in the pulsed discharge signal applied by the drive circuitry to the control terminal of the electronic switch;
increase the duration of the pulses in the pulsed discharge signal in response to the pulse duration comparator indicating that the actual duration of the pulses in the pulsed discharge signal is shorter than the reference duration for the pulses in the pulsed discharge signal; and
refrain from increasing the duration of the pulses in the pulsed discharge signal in response to the pulse duration comparator indicating that the actual duration of the pulses in the pulsed discharge signal has reached or exceeded the reference duration for the pulses in the pulsed discharge signal.

2. The circuit of claim 1, wherein:
the pulse duration generator is coupled to the sensing node via a comparator circuit configured to provide a comparison signal having a first value or a second value in response to the voltage at the control terminal being higher or lower than a reference threshold, respectively, wherein the comparison signal is indicative of the duration of the pulses in the pulsed discharge signal applied by the drive circuitry to the control terminal of the electronic switch; and
the pulse duration generator is configured to be started in response to the comparison signal from the comparator circuit having the first value and stopped in response to the comparison signal from the comparator circuit having the second value.

3. The circuit of claim 2, wherein the reference threshold of the comparator circuit is selectively configurable.

4. The circuit of claim 2, wherein:
the reference generator comprises a first reference current generator configured to charge a first reference capacitor in response to the pulses in the pulsed discharge signal;
the pulse duration generator comprises a second reference current generator configured to charge a second reference capacitor in response to the comparison signal from the comparator circuit having the first value; and
the pulse duration comparator comprises a charge comparator having charge comparator inputs coupled to the first reference capacitor and the second reference capacitor, respectively, as well as a charge comparator output coupled to the pulse duration control circuitry wherein the pulse duration control circuitry increases the duration of the pulses in the pulsed discharge signal or refrains from increasing the duration of the pulses in the pulsed discharge signal based on the charge comparator output.

5. The circuit of claim 4, wherein a first current from the first reference current generator and a first capacitance of the first reference capacitor have a first ratio equal to a second ratio of a second current from the second reference current generator and a second capacitance of the second reference capacitor.

6. The circuit of claim 1, wherein the reference generator is configured to produce a second reference signal indicative of a selectively configurable reference duration for the pulses in the pulsed discharge signal.

7. The circuit of claim 6, wherein the reference generator comprises:
a charge current generator; and
a bank of capacitors configured to be coupled to the charge current generator in a selectively determined parallel connection of capacitors in the bank of capacitors, wherein an electrical charge charged on the selectively determined parallel connection of capacitors is indicative of the selectively configurable reference duration for the pulses in the pulsed discharge signal.

8. The circuit of claim 1, wherein the pulse duration control circuitry is configured to assert a stop command towards the drive circuitry to cause the drive circuitry to refrain from increasing the duration of the pulses in the pulsed discharge signal in response to the pulse duration comparator indicating that the actual duration the pulses in the pulsed discharge signal has reached or exceeded the reference duration for the pulses in the pulsed discharge signal.

9. The circuit of claim 8, wherein the pulse duration control circuitry comprises a counter configured to have the count therein:
incremented in response to the pulse duration comparator indicating that the actual duration the pulses in the pulsed discharge signal is shorter than the reference duration for the pulses in the pulsed discharge signal; and
stopped in response to the pulse duration comparator indicating that the actual duration the pulses in the pulsed discharge signal has reached or exceeded the reference duration for the pulses in the pulsed discharge signal.

10. A system, comprising:
an electronic switch having a control terminal and configured to provide an electrical discharge path for an energized element in response to a pulsed discharge signal comprising pulses applied to the control terminal; and
a circuit comprising:
drive circuitry coupled to the control terminal of the electronic switch and configured to apply the pulsed discharge signal to the control terminal;
a sensing node coupled to the control terminal and configured to sense a voltage at the control terminal; and
a feedback network from the sensing node to the drive circuitry, wherein the drive circuitry is configured to produce the pulses in the pulsed discharge signal with a duration that is a function of the voltage at the control terminal sensed at the sensing node, and wherein the feedback network comprises:
a reference generator configured to produce a reference signal indicative of a reference duration for the pulses in the pulsed discharge signal;
a pulse duration generator coupled to the sensing node and configured to produce a duration signal indicative of an actual duration of the pulses in the pulsed discharge signal;
a pulse duration comparator coupled to the reference generator and the pulse duration generator, the pulse duration comparator configured to compare the actual duration the pulses in the pulsed discharge signal with the reference duration for the pulses in the pulsed discharge signal; and
pulse duration control circuitry coupled to the drive circuitry and the pulse duration comparator, wherein the pulse duration control circuitry is configured to:
control the duration of the pulses in the pulsed discharge signal applied by the drive circuitry to the control terminal of the electronic switch;
increase the duration of the pulses in the pulsed discharge signal in response to the pulse duration comparator indicating that the actual duration of the pulses in the pulsed discharge signal is shorter than the reference duration for the pulses in the pulsed discharge signal; and
refrain from increasing the duration of the pulses in the pulsed discharge signal in response to the pulse duration comparator indicating that the actual duration of the pulses in the pulsed discharge signal has reached or exceeded the reference duration for the pulses in the pulsed discharge signal.

11. The system of claim 10, further comprising an electric motor having at least one winding configured to be selectively energized via at least one phase switch coupled therewith, wherein the electronic switch comprises the at least one phase switch.

12. The system of claim 11, further comprising a motor vehicle, wherein the electric motor is configured to provide electric traction power for the motor vehicle, wherein the motor vehicle comprises a direct-current link capacitor, and wherein the electronic switch is configured to provide the electrical discharge path for the direct-current link capacitor.

13. A method of operating an electronic switch providing an electrical discharge path for an energized element, the electronic switch having a control terminal, the method comprising:
applying to the control terminal a pulsed discharge signal causing the electronic switch to become conductive and provide the electrical discharge path for the energized element;
sensing a voltage at the control terminal of the electronic switch;
producing the pulsed discharge signal in a closed-loop feedback arrangement as a function of the voltage sensed at the control terminal;
producing a reference signal indicative of a reference duration for pulses in the pulsed discharge signal;
producing a duration signal indicative of an actual duration the pulses in the pulsed discharge signal;
performing, based on the reference signal and the duration signal, a comparison of the actual duration the pulses in the pulsed discharge signal with the reference duration for the pulses in the pulsed discharge signal; and
controlling a duration of the pulses in the pulsed discharge signal applied to the control terminal of the electronic switch based on the comparison.

14. The method of claim 13, further comprising controlling the duration of the pulses by increasing the duration of the pulses in the pulsed discharge signal in response to the comparison indicating that the actual duration the pulses in the pulsed discharge signal is shorter that the reference duration for the pulses in the pulsed discharge signal.

15. The method of claim 14, wherein a pulse duration comparator comprises a charge comparator having charge comparator inputs coupled to a first reference capacitor and a second reference capacitor, respectively, and a charge comparator output coupled to pulse duration control circuitry, and the method further comprises:
charging the first reference capacitor in response to the pulses in the pulsed discharge signal;
charging the second reference capacitor in response to a comparison signal from a comparator circuit having a first value; and
increasing, by the pulse duration control circuitry, the duration of the pulses in the pulsed discharge signal based on the charge comparator output.

16. The method of claim 13, further comprising controlling the duration of the pulses by refraining from increasing the duration of the pulses in the pulsed discharge signal in response to the comparison indicating that the actual duration of the pulses in the pulsed discharge signal has reached or exceeded the reference duration for the pulses in the pulsed discharge signal.

17. The method of claim 16, wherein a pulse duration comparator comprises a charge comparator having charge comparator inputs coupled to a first reference capacitor and a second reference capacitor, respectively, and a charge comparator output coupled to pulse duration control circuitry, and the method further comprises:
charging the first reference capacitor in response to the pulses in the pulsed discharge signal;
charging the second reference capacitor in response to a comparison signal from a comparator circuit having a first value; and
refraining from increasing, by the pulse duration control circuitry, the duration of the pulses in the pulsed discharge signal based on the charge comparator output.

18. The method of claim 13, wherein a pulse duration generator is coupled to a sensing node via a comparator circuit, and the method further comprises:
providing, by the comparator circuit, a comparison signal having a first value or a second value in response to the voltage at the control terminal being higher or lower than a reference threshold, respectively, the comparison signal being indicative of the duration of the pulses in the pulsed discharge signal applied by drive circuitry to the control terminal of the electronic switch; and
starting the pulse duration generator in response to the comparison signal from the comparator circuit having the first value; or
stopping the pulse duration generator in response to the comparison signal from the comparator circuit having the second value.

19. The method of claim 13, further comprising producing a second reference signal indicative of a selectively configurable reference duration for the pulses in the pulsed discharge signal.

20. The method of claim 13, further comprising asserting a stop command towards drive circuitry to cause the drive circuitry to refrain from increasing the duration of the pulses in the pulsed discharge signal in response to a pulse duration comparator indicating that the actual duration the pulses in the pulsed discharge signal has reached or exceeded the reference duration for the pulses in the pulsed discharge signal.
